(19) United States
(12) Patent Application Publication
(10) Pub. No.: US 2004/0151036 A1
(43) Pub. Date: Aug. 5, 2004

(54) Magnetic head for performing perpendicular magnetic recording in a disk drive

(75) Inventors: Yuka Aoyagi, Tachikawa-shi (JP); Kazuhito Shimomura, Akishima-shi (JP); Akihiko Takeo, Kunitachi-shi (JP); Masaru Atsumi, Ome-shi (JP)

Correspondence Address: PILLSBURY WINTHROP, LLP, P.O. BOX 10500, MCLEAN, VA, 22102, US

(73) Assignee: KABUSHIKI KAISHA TOSHIBA, Tokyo (JP)

(21) Appl. No.: 10/674,792

(22) Filed: Oct. 1, 2003

(30) Foreign Application Priority Data
Oct. 1, 2002 (JP) 2002-288907

(51) Int. Cl. G11C 7/00

(52) U.S. Cl. 365/199

(57) ABSTRACT

Disclosed herein is a magnetic head including a main magnetic pole and a return yoke. The magnetic head can suppress a side writing at an edge of the return yoke even if the soft magnetic layer of a disk is saturated. The magnetic head further includes a single-pole type head that is used as write head.

### CROSS-REFERENCE TO RELATED APPLICATIONS

This application is based upon and claims the benefit of priority from the prior Japanese Patent Application No. 2002-288907, filed Oct. 1, 2002, the entire contents of which are incorporated herein by reference.

### BACKGROUND OF THE INVENTION

1. Field of the Invention

The present invention relates to disk drives. More particularly, it relates to a magnetic head for performing perpendicular magnetic recording in a disk drive.

2. Description of the Related Art

In recent years, more and more disk drives, a representative example of which is a hard disk, perform perpendicular magnetic recording. A hard disk drive that carries out perpendicular magnetic recording comprises a magnetic head and a disk-shaped recording medium. The magnetic head includes a single-pole type (SPT) head. The disk-shaped recording medium (hereinafter referred to as “disk”) is a double-layered perpendicular recording medium. The magnetic head performs perpendicular magnetic recording on the disk.

The magnetic head comprises a write head and a read head. The write head is an SPT. The read head is a GMR (Giant Magnetoresistive) element in most cases. Both the write head and the read head are mounted on a slider, spaced part from each other. The disk has a double-layered structure and comprises a substrate, a recording magnetic layer, and a soft magnetic layer. The soft magnetic layer is interposed between the substrate and the recording magnetic layer.

The main magnetic pole of the SPT generates a magnetic flux (recording magnetic field). The magnetic flux passes through the magnetic recording layer and the soft magnetic layer before it reaches the return yoke of the SPT. Thus, perpendicular magnetic recording is achieved. In other words, the magnetic coupling between the magnetic head and the disk results in the perpendicular magnetic recording.

A magnetic disturbance other than the return yoke, which has high-saturated flux density, may exist in the magnetic head. Alternatively, the soft magnetic layer of the magnetic head may be saturated. In either case, so-called “side writing” is likely to occur. A side writing is a phenomenon in which the magnetic flux extends to the circumferential edge of the return yoke, not concentrating at the center thereof. Due to the side writing, an intense magnetic field acts on the disk from the edge of the return yoke. Consequently, data is recorded (written) on an undesired part of the disk, or a recorded part of the disk is erased.

The side writing greatly lowers the quality of signals recorded on the disk by perpendicular magnetic recording. Measures should be taken against the side writing. Hitherto the following measures have been proposed.

The first measure is to set a saturated magnetic flux density at the distal end of the SPT, which is higher than the saturated magnetic flux density of the return yoke. (Refer to, for example, Jpn. Pat. Appln. KOKAI Publication No. 4-221410.) If this measured is taken, however, the magnetic flux extends to the edge of the return yoke when the soft magnetic layer is saturated. The flux inevitably causes a side writing at the edge of the return yoke.

The second measure is to project a part of the return yoke toward the main magnetic pole of the SPT. (Refer to, for example, Jpn. Pat. Appln. KOKAI Publication No. 2002-92820.) This prevents the magnetic flux entering the return yoke from extending in the track-width direction of the disk. The noise at the track edge can therefore be reduced. This measure, however, cannot completely eliminate the side writing resulting from the saturation of the soft magnetic layer.

The third measure is to accomplish perpendicular magnetic recording, without saturating the soft magnetic layer. That is, the saturated flux density and thickness of the film provided beneath the magnetic recording layer are adjusted, and so are the saturated flux density and recording wavelength of the magnetic recording layer. (Refer to, for example, Jpn. Pat. Appln. KOKAI Publication No. 2-81301.)

It is confirmed, however, that the soft magnetic layer is saturated when the recording current is too large even if the saturated flux density at the main magnetic pole or the soft magnetic layer is set at a specific value.

Generally it is desired that the recording current supplied to the write head to record data magnetically be large enough to fully use the saturation characteristics of the main magnetic pole, return yoke and soft magnetic layer. If the recording current is excessive, however, the soft magnetic layer will be saturated, inevitably causing a side writing at the edge of the return yoke.

### BRIEF SUMMARY OF THE INVENTION

In accordance with one embodiment of the present invention, there is provided a disk drive comprising a magnetic head that can suppress occurrence of a side writing.

The disk drive comprises a disk-shaped recording medium for perpendicular magnetic recording and a magnetic head. The recording medium includes a soft magnetic layer and a magnetic recording layer provided on the soft magnetic layer. The magnetic head includes a main magnetic pole and a return yoke. The main magnetic pole is configured to generate a recording magnetic field extends perpendicular to the magnetic recording layer. The return yoke forms a magnetic path which guides, through the soft magnetic layer, a magnetic flux driving from the recording magnetic field generated by the main magnetic pole. The return yoke has an edge that opposes a surface of the disk-shaped recording medium. The edge of the return yoke is so shaped that a ratio of the field intensity at that edge to the intensity of the magnetic field generated by the main magnetic pole is equal to or less than a predetermined value.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of the magnetic head incorporated in an embodiment of the present invention;

FIG. 2 is a block diagram showing the major components of the disk drive that is the embodiment of the invention;

FIG. 3 is a diagram illustrating the structure of a disk-shaped recording medium used in the embodiment;

FIGS. 4A to 4C are diagrams representing the shape of the return yoke used in the embodiment;

FIG. 5 is a graph showing the influence a side writing imposes in the embodiment; and

FIGS. 6A to 6C are diagrams illustrating another embodiment of the present invention.

### DETAILED DESCRIPTION OF THE INVENTION

An embodiment of this invention will be described, with reference to the accompanying drawings.

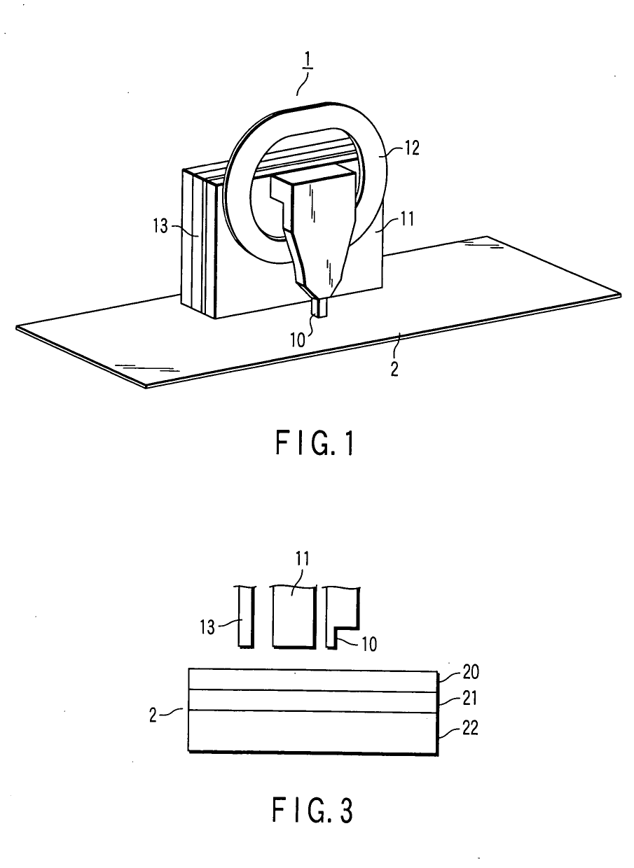

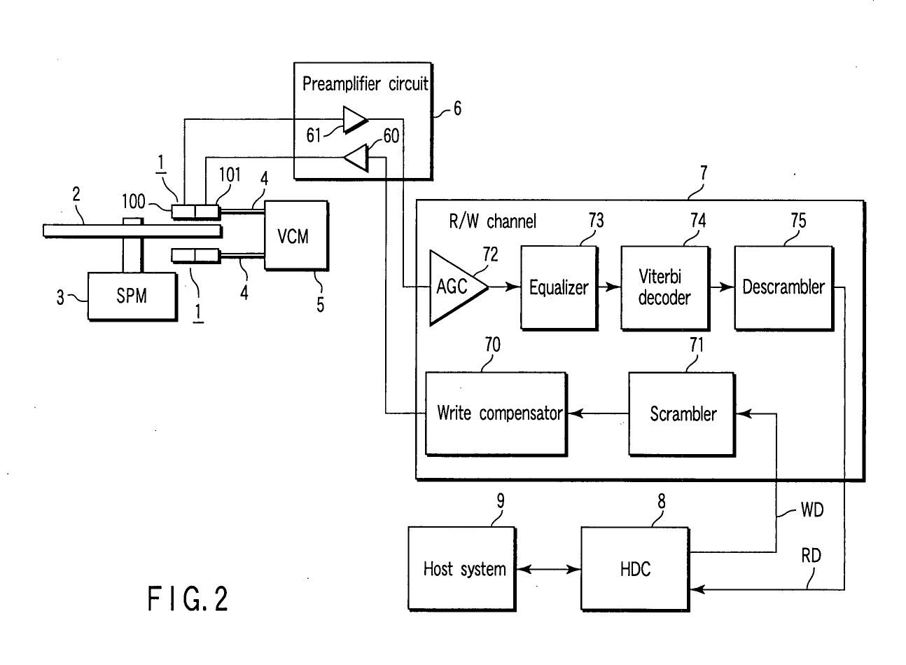

FIG. 1 is a perspective view of the magnetic head incorporated in the embodiment of the invention. FIG. 2 is a block diagram showing the major components of the embodiment. FIG. 3 a diagram illustrating the structure of a disk-shaped recording medium used in the embodiment.

### Disk Drive

The disk drive, which is the embodiment of the invention, will be described with reference to FIG. 2.

The disk drive has a magnetic head 1, a disk 2, a read/write (R/W) channel 7, and a disk controller (HDC) 8. The disk 2 is a double-layered, perpendicular magnetic recording medium.

The disk 2 is fixed to a spindle motor (SPM) 3 and can be rotated. The magnetic head 1 comprises a read head 100 and a write head 101, which are mounted on a slider. The head 1 is mounted on an actuator 4 and can be moved in the radial direction of the disk 2. The actuator 4 is driven by a voice coil motor (VCM) 5.

The read head 100 reads data signals from the disk 2. The R/W channel 7 includes a read channel and a write channel. The read channel processes the data signals, decoding the read data (RD). The write channel encodes and outputs the write data (WD) transferred from the HDC 8.

The read channel is a signal-processing circuit of PRML (Partial Response Maximum Likelihood) type. The read channel comprises an AGC amplifier 72, equalizer 73, Viterbi decoder 74 and descrambler 75. The AGC amplifier 72 receives a data signal from the read amplifier 61 of a preamplifier circuit 6. It performs an automatic gain control on the data signal, maintaining it at a constant level.

The equalizer 73 is a unit for processing digital signals and includes a low-pass filter, A/D converter and digital filter. The descrambler 75 can convert the write data scrambled by the scrambler 71 of the write channel, back to the write data (WD).

The preamplifier circuit 6 has a write amplifier 60 in addition to the read amplifier 61. The read amplifier 61 amplifies the data signal read by the read head 100. The data signal amplified is supplied to the R/W channel 7. The write amplifier 60 converts the write-data signal output from the R/W channel 7, into a write current. The write current is supplied to the write head 101.

The write channel of the R/W channel 7 comprises a write compensator 70 and a scrambler 71. The scrambler 71 is a circuit for scrambling the write signal supplied from the HDC 8. It is an exclusive OR circuit in most case. The write compensator 70 includes a precoder. The precoder is a circuit that imposes interference inverse to the PR (Partial Response) equalization.

The HDC 8 functions as interface between the disk drive and a host system 9. It receives write data (WD) from the host system 9 and transfers read data (RD) to the host system 9.

### Magnetic Head and Disk

As FIG. 1 shows, the magnetic head 1 comprises a write head and a read head. The write head is a single-pole type (SPT) head. The read head includes a GMR element 13. Note that the write head characterizes the present embodiment. By contrast, the read head is of the known type, and will not be described.

The write head has a main magnetic pole 10, a return yoke 11 and an excitation coil 12. A seal isolates the write head and the read head from each other.

When a write current is supplied to the excitation coil 12, the main magnetic pole 10 generates a recording magnetic field. The recording magnetic field extends in the vertical direction. Its intensity is proportional to the write current supplied to the coil 12. The coil 12 receives a write current from the write amplifier 60. The return yoke 11, also known as “auxiliary magnetic pole,” intensifies the magnetic flux deriving from the recording magnetic field. Thus, it forms a magnetic circuit (magnetic path).

The structure of the disk 2 and the principle of perpendicular magnetic recording will be explained with reference to FIG. 3.

As FIG. 3 depicts, the disk 2 is a double-layered recording medium. It comprises a magnetic recording layer 20, a soft magnetic layer 21, and a substrate 22. The recording layer 20 exhibits perpendicular magnetic anisotroply. The soft magnetic layer 21 is interposed between the recording layer 20 and the substrate 22. It conducts the magnetic flux from the main magnetic pole 10 in the vertical direction. Thus, the layer 21 helps to magnetize the recording layer 20 in the vertical direction. The magnetic flux deriving from the main magnetic pole 10 passes through the magnetic recording layer 20, soft magnetic layer 21 and return yoke 11. Hence, the layers 20 and 21 and yoke 11 constitute a magnetic circuit.

In the magnetic circuit, the magnetic flux (recording magnetic flux) generated by the pole 10 passes through the magnetic recording layer 20 and soft magnetic layer 21 and reaches the return yoke 11. The flux achieves perpendicular magnetic recording on the magnetic recording layer 20. That is, the write head (SPT) and the disk 2 are magnetically coupled. Data signals are thereby recorded on the disk 2 by means of perpendicular magnetic recording.

### Return Yoke

The intensity of the magnetic field at the write head is determined by the saturated flux densities of the main magnetic pole 10 and return yoke 11, the saturated flux density and thickness of the soft magnetic layer 21, and the write current flowing in the coil 12. As is known in the art, the shape of the return yoke 11 is related to the intensity the magnetic field has at two ends of the return yoke 11.

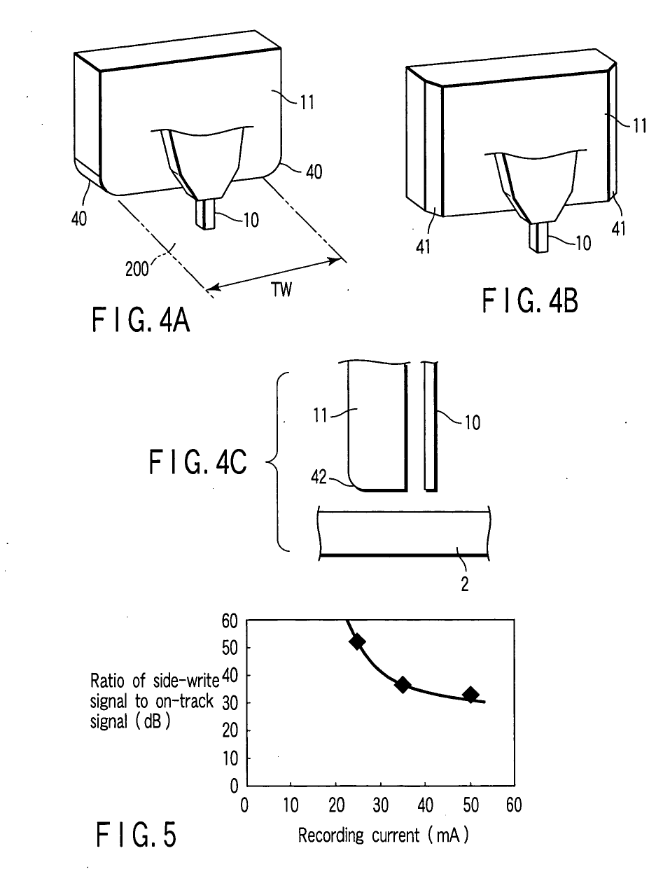

The term “shape of the return yoke 11” means the shape of that part which faces the surface of the disk 2. The term “ends of the return yoke 11” means those parts of the yoke 11 which are spaced apart in the widthwise direction TW of the track 200 that is provided on the disk 2 as illustrated in FIG. 4A. Thus, the shape of the return yoke 11, which influences the intensity of the magnetic field, determines the way the magnetic flux that extends in the widthwise direction of the track 200.

The relation between the shape of the return yoke 11 and the intensity of the magnetic field will be described, with reference to the FIGS. 4A to 4C and FIG. 5.

FIG. 4A is a front view of a return yoke 11. The return yoke 11 has two rounded horizontal edges 40 that are spaced apart in the widthwise direction TW of the track 200. The horizontal edges 40 have been rounded, by means of cutting or chamfering. Therefore, the return yoke 11 has the surface which is opposite the track 200 and which has an area smaller than any other surface. The return yoke 11 shown in FIG. 4A will be called “type A,” for convenience of explanation.

FIG. 4B is a font view of another type of a yoke 11. This return yoke 11 has two rounded vertical edges 41 that are spaced apart in the widthwise direction TW of the track 200. The vertical edges 41 have been rounded, by means of cutting or chamfering. The return yoke 11 shown in FIG. 4B will be called “type B,” for convenience of explanation.

FIG. 4C is a side view of still another type of a return yoke 11, which will be called “type C.” As seen from FIG. 4C, the lower side of this yoke 11, which faces the disk 2, is rounded at the rear edge 42 that faces away from the main magnetic pole 10. The edge 42 has been formed by either cutting or chamfering.

The relation between the shape of each of these return yokes 11 (types A, B and C) and the intensity the magnetic field has at the rounded edge of the yoke 11 will be discussed in terms of the ratio of the field intensity actually measured to the field intensity actually measured at the tip of the main magnetic pole 10.

In the case of an ordinary return yoke 11 (FIG. 1) having no rounded edges, the field intensity at each edge is about 15% of the field intensity at the main magnetic pole 10. At this value of the magnetic field, a side writing develops at each edge of the return yoke 11. It is confirmed that the side writing is likely to occur when the main magnetic pole 10 generates a recording magnetic field, saturating the soft magnetic layer 21. In view of this, the side writing is regarded as a phenomenon in which the magnetic flux derived from the recording magnetic field reaches to the return yoke 11, not concentrating at the center of the yoke 11.

In the case of the return yoke 11 of type A, the field intensity at each rounded edge 40 is about 7% of the field intensity at the main magnetic pole 10. In the case of the return yoke 11 of type B, the field intensity at each rounded edge 41 is about 9% of the field intensity at the main magnetic pole 10. In the case of the return yoke 11 of type C, the field intensity at the rounded edge 42 is about 9% of the field intensity at the main magnetic pole 10.

The field intensity at each rounded edge of the return yokes 11 of types A, B and C according to the invention is lower than the field intensity at each edge of the ordinary return yoke 11 shown in FIG. 1. This is because the magnetic flux emanating from the surface of the disk 2 concentrates at the center of the yoke 11 since the rounded edge 40, 41 or 42 is more spaced than the center of the yoke 11 from the surface of the disk 2. Hence, the side writing caused by an intense magnetic field emanating from any edge of the return yoke 11 can be suppressed with the write head incorporated in the magnetic head 1.

In the present embodiment, the return yoke 11 has a recess configuration, with at least one edge rounded by chamfering or cutting, which helps to suppress the side writing. Nonetheless, the rounded edge may be replaced by one having a triangular cross section or a stepped cross section. The edge having such a cross section can suppress the side writing, too.

The influence of a side writing occurring at the return yoke 11 of type A (FIG. 4A) incorporated in the disk drive will be explained in detail, with reference to FIG. 5.

Assume that the lower side of the return yoke 11 (FIG. 4A), which opposes the disk 2, is a rectangle that extends 80 μm in the widthwise direction TW of the track 200. Then, the rounded edges 40 are each spaced by 40 μm from the recording center on the disk 2.

FIG. 5 represents the relation between the recording current (write current) supplied to the write head and the ratio of a side-write signal to an on-track signal. If the write current is 30 mA or less, no bit-error rate (BER) due to the side writing remains at normal value. If the ratio of the side-write signal to the on-track signal is less than 40 dB, the side writing occurring at either rounded edge of the return yoke 11 falls to a low level.

If the ratio of the side-write signal to the on-track signal exceeds 40 dB, the side writing at either rounded edge of the return yoke 11 is at so high a level that a read error will develop for all probability. In the worst case, the side writing may be so prominent to rewrite (or over-write) the servo data that is recorded on the disk 2. If the servo data is rewritten, the magnetic head 1 can no longer be positioned as is desired.

### Another Embodiment

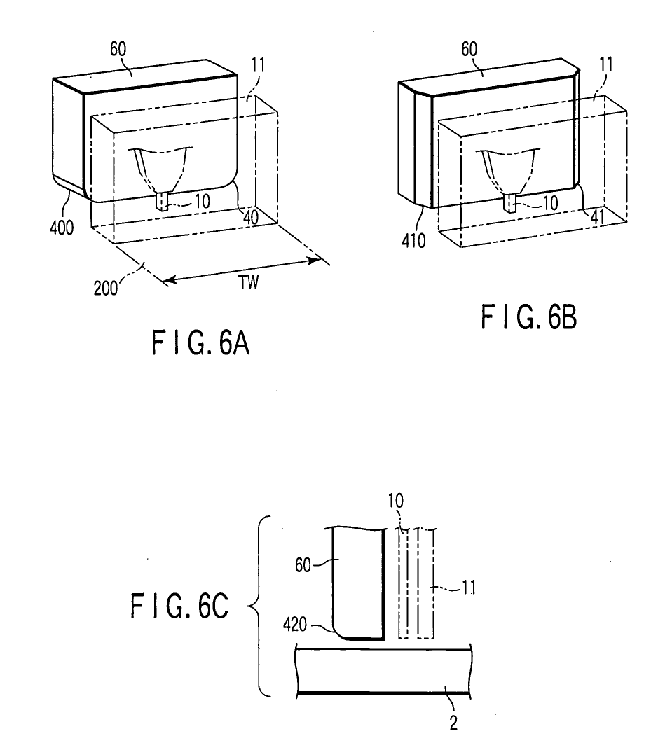

FIGS. 6A to 6C illustrate another embodiment of the present invention, more precisely three write heads, each for use in a magnetic head 1.

These write heads have a write shield 60 each. The write shield 60 is positioned, opposing the main magnetic pole 10. It is interposed between the main magnetic pole 10a and the return yoke 11. The shield 60 is a member that protects the magnetic head 1 from the external magnetic field (external magnetic disturbance). In short, the write heads of FIGS. 6A, 6B and 6C are identical to those shown in FIGS. 4A, 4B and 4C, respectively, except in that the yoke 11 and write shield 60 are positioned symmetrically with respect to the main magnetic pole 10.

Like the return yoke 11, the write shield 60 of the write head shown in FIGS. 6A, 6B or 6C is so shaped to suppress the side writing that occurs at its each edge.

More specifically, the write head shown in FIG. 6A (front view) has a write shield 60 shaped like the return yoke 11 (type A) illustrated in FIG. 4A. That is, the write shield 60 has two rounded horizontal edges 400 that are spaced apart in the widthwise direction TW of the track 200 and have been rounded, by means of cutting or chamfering. The write head shown in FIG. 6B (front view) has a write shield 60 shaped like the return yoke 11 (type B) depicted in FIG. 4B. Namely, the write shield 60 has two rounded vertical edges 410 that are spaced apart in the widthwise direction TW of the track 200 and have been rounded, by means of cutting or chamfering.

The write head shown in FIG. 6C (side view) has a write shield 60 shaped like the return yoke 11 (type C) shown in FIG. 4C. More precisely, the lower side of this write shield 60, which faces the disk 2, is rounded at the rear edge 420 that faces away from the main magnetic pole 10. The rear edge 420 has been formed by either cutting or chamfering.

Having the shape specified above, the write shields 60 can suppress the side writing that occurs at its each edge, as the return yokes 11 used in the embodiment described above.

In the magnetic head 1 of either embodiment, the side writing occurring at each edge of the return yoke 11 or write shield 60 can suppressed. The soft magnetic layer 21 of the disk 2 may be saturated causing a side writing, particularly when the write current is increased. Nonetheless, the side writing can be controlled well, thanks to the special structure of the magnetic head 1. Since the side writing is suppressed, data is not recorded (written) on an undesired part of the disk, or a recorded part of the disk is not demagnetized.

Thus, in the disk drive that performs perpendicular magnetic recording, the side writing at any edge of the return yoke can be suppressed even if the soft magnetic layer is saturated. As a result, the signals recorded on the disk by perpendicular magnetic recording can have high quality.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A disk drive comprising:
a disk-shaped recording medium for perpendicular magnetic recording, which includes a soft magnetic layer and a magnetic recording layer provided on the soft magnetic layer; and
a magnetic head which includes a main magnetic pole for generating a recording magnetic field extending perpendicular to the magnetic recording layer and a return yoke for forming a magnetic path which guides, through the soft magnetic layer, a magnetic flux driving from the recording magnetic field generated by the main magnetic pole, said return yoke having a center part and an edge which opposes a surface of the disk-shaped recording medium and which is so shaped that a ratio of the field intensity at that edge to the intensity of the magnetic field generated by the main magnetic pole is equal to or less than a predetermined value for suppressing a side writing caused by an intense magnetic field emanating from the edge of the return yoke.

2. The disk drive according to claim 1, wherein said edge of the return yoke has a surface which is opposite the surface of the disk-shaped recording medium, which has an area smaller than any other surface and which therefore helps to suppressing a side writing caused by an intense magnetic field emanating from the edge of the return yoke.

3. The disk drive according to claim 1, wherein said edge of the return yoke is so shaped that the edge is more spaced than the center part from a track which is formed on the surface of the disk-shaped recording medium.

4. The disk drive according to claim 1, wherein the return yoke is so shaped that first distance between the edge and the main magnetic pole is more than second distance between the center part and the main magnetic pole.

5. The disk drive according to claim 1, wherein said edge of the return yoke is so shaped that the distance between any part and the main magnetic pole is proportional to the distance between the part and the surface of the disk-shaped recording medium.

6. The disk drive according to claim 1, wherein the magnetic head further includes a write shield which opposes the return yoke across the main magnetic pole and which has an edge opposing a surface of the disk-shaped recording medium and so shaped that a surface which is opposite the surface of the disk-shaped recording medium has an area smaller than any other surface.

7. The disk drive according to claim 6, wherein said edge of the write shield is so shaped that the edge is more spaced than the center part from a track which is formed on the surface of the disk-shaped recording medium.

8. The disk drive according to claim 6, wherein the write shield is so shaped that first distance between the edge and the main magnetic pole is more than second distance between the center part and the main magnetic pole.

9. The disk drive according to claim 6, wherein said edge of the write shield is so shaped that the distance between any part and the main magnetic pole is proportional to the distance between the part and the surface of the disk-shaped recording medium.

10. The disk drive according to claim 1, wherein the magnetic head further includes a write shield which opposes the return yoke across the main magnetic pole; return yoke has an edge opposing a surface of the disk-shaped recording medium and so shaped that a surface substantially parallel to the surface of the disk-shaped recording medium has an area smaller than any other surface; and the write shield has an edge opposing a surface of the disk-shaped recording medium and so shaped that a surface substantially parallel to the surface of the disk-shaped recording medium has an area smaller than any other surface.

11. A magnetic head for use in a disk drive that uses a disk-shaped recording medium for perpendicular magnetic recording, which includes a soft magnetic layer and a magnetic recording layer provided on the soft magnetic layer, said magnetic head comprising:
a read-head element which detects a magnetic flux from the magnetic recording layer, said magnetic flux corresponding data recorded by means of perpendicular magnetic recording;
a write-head element which is spaced from the read-head element and which includes a main magnetic pole for generating a recording magnetic field extending perpendicular to the magnetic recording layer and a return yoke for forming a magnetic path which guides, through the soft magnetic layer, a magnetic flux driving from the recording magnetic field generated by the main magnetic pole, said return yoke having a center part and an edge which opposes a surface of the disk-shaped recording medium and which is so shaped that a ratio of the field intensity at that edge to the intensity of the magnetic field generated by the main magnetic pole is equal to or less than a predetermined value for suppressing a side writing caused by an intense magnetic field emanating from the edge of the return yoke.

12. The magnetic head according to claim 11, wherein said edge of the return yoke has a surface which is opposite the surface of the disk-shaped recording medium, which has an area smaller than any other surface and which therefore helps to suppressing a side writing caused by an intense magnetic field emanating from the edge of the return yoke.

13. The magnetic head according to claim 11, wherein said edge of the return yoke is so shaped that the edge is more spaced than the center part from a track which is formed on the surface of the disk-shaped recording medium.

14. The magnetic head according to claim 11, wherein the return yoke is so shaped that first distance between the edge and the main magnetic pole is more than second distance between the center part and the main magnetic pole.

15. The magnetic head according to claim 11, wherein said edge of the return yoke is so shaped that the distance between any part and the main magnetic pole is proportional to the distance between the part and the surface of the disk-shaped recording medium.

16. The magnetic head according to claim 11, further including a write shield which opposes the return yoke across the main magnetic pole and which has an edge opposing a surface of the disk-shaped recording medium and so shaped that a surface which is opposite the surface of the disk-shaped recording medium has an area smaller than any other surface.

17. The magnetic head according to claim 16, wherein said edge of the write shield is so shaped that the edge is more spaced than the center part from a track which is formed on the surface of the disk-shaped recording medium.

18. The magnetic head according to claim 16, wherein the write shield is so shaped that first distance between the edge and the main magnetic pole is more than second distance between the center part and the main magnetic pole.

19. The magnetic head according to claim 16, wherein said edge of the write shield is so shaped that the distance between any part and the main magnetic pole is proportional to the distance between the part and the surface of the disk-shaped recording medium.

20. The magnetic head according to claim 11, which further includes a write shield which opposes the return yoke across the main magnetic pole, said edge of the return yoke is so shaped that a surface which is substantially parallel to the surface of the disk-shaped recording medium and which has an area smaller than any other surface, and the write shield has an edge opposing a surface of the disk-shaped recording medium and so shaped that a surface substantially parallel to the surface of the disk-shaped recording medium has an area smaller than any other surface.
